(19) United States
(12) Patent Application Publication
(10) Pub. No.: US 2019/0157160 A1
(43) Pub. Date: May 23, 2019

(54) BULK FINFET WITH SELF-ALIGNED BOTTOM ISOLATION

(71) Applicant: QUALCOMM Incorporated, San Diego, CA (US)

(72) Inventors: Cimang LU, Shanghai (CN); Stanley Seungchul SONG, San Diego, CA (US); Periannan CHIDAMBARAM, San Diego, CA (US)

(21) Appl. No.: 15/817,452

(22) Filed: Nov. 20, 2017

(51) Int. Cl. H01L 21/8234; H01L 27/088; H01L 29/06; H01L 21/308

(52) U.S. Cl. CPC H01L 21/823481; H01L 27/0886; H01L 21/3086; H01L 21/823431; H01L 29/0649

(57) ABSTRACT

Aspects of the disclosure are directed to a semiconductor device. The semiconductor device may include a plurality of fins formed on a semiconductor substrate including a bulk semiconductor material, a plurality of shallow trench isolation (STI) trenches formed between the plurality of fins, a hardmask formed around the plurality of fins, and a plurality of fin bottom portions formed below the plurality of fins.

### BACKGROUND

### Field

Aspects of the present disclosure relate generally to semiconductor transistors and, more particularly, to minimizing punch-through leakage current in bulk Fin Field-Effect Transistors (FinFETs).

### Background

Fin Field-Effect Transistor (FinFET) devices have been developed to replace conventional planar bulk Metal-Oxide-Semiconductor Field-Effect Transistors (MOSFETs) in advanced Complementary Metal-Oxide-Semiconductor (CMOS) technology due to their improved short-channel effect immunity. A problem with bulk FinFET devices, however, is that a leakage path from source to drain exists through a portion of the fin lying below the channel. The leakage of current from source to drain through the lower (un-gated) part of the fin, commonly known as punch-through leakage, causes an undesirable increase of static power consumption. One known solution is implanting a punch-through-stopper (PTS) dopant in a portion of the fin directly below the channel. However, the impurities doped by the punch-through-stopper (PTS) implantation may diffuse into the channel region, increasing the variability due to random dopant fluctuation (RDF) and lowering the carrier mobility of the channel region. Thus, there continues to be a need for a solution for punch-through leakage.

### SUMMARY

The following presents a simplified summary of one or more embodiments to provide a basic understanding of such embodiments. This summary is not an extensive overview of all contemplated embodiments, and is intended to neither identify key or critical elements of all embodiments nor delineate the scope of any or all embodiments. Its sole purpose is to present some concepts of one or more embodiments in a simplified form as a prelude to the more detailed description that is presented later.

A method according to one aspect is described. The method may include providing a semiconductor substrate including a bulk semiconductor material, forming a plurality of fins from the bulk semiconductor material, forming shallow trench isolation (STI) trenches between the plurality of fins, forming a hardmask around the plurality of fins, forming a plurality of spacers on sidewalls of the plurality of fins protecting the sidewalls and exposing bottom portions of the fins where isolation is formed, and selectively etching and oxidizing the exposed bottom portions of the fins.

A semiconductor device according to one aspect is described. The semiconductor device may include a plurality of fins formed on a semiconductor substrate including a bulk semiconductor material, a plurality of STI trenches formed between the plurality of fins, a hardmask formed around the plurality of fins, and a plurality of fin bottoms formed below the plurality of fins.

These and other aspects of the invention will become more fully understood upon a review of the detailed description, which follows. Other aspects, features, and embodiments of the invention will become apparent to those of ordinary skill in the art, upon reviewing the following description of specific, exemplary embodiments of the invention in conjunction with the accompanying figures.

### BRIEF DESCRIPTION OF THE DRAWINGS

FIG. 1 illustrates an anti-punch-through (ATP) implantation of the prior art;

FIG. 2 illustrates a tail inside the fin regions ATP implantation of the prior art;

FIGS. 3A-3E show a process of forming a semiconductor structure in accordance to one aspect of the invention; and

FIG. 4 shows a semiconductor device in accordance to one aspect of the invention.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form to simplify explanation and avoid obscuring such concepts.

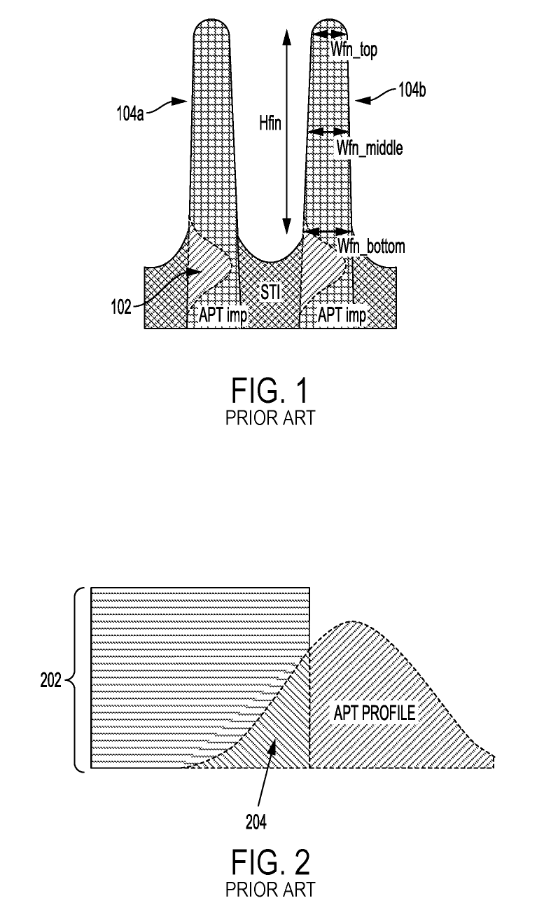

FIG. 1 illustrates an anti-punch-through (ATP) implantation 102 of the prior art. The anti-punch-through (ATP) implantation 102 is performed beneath fins 104a and 104b. More specifically, ATP layers are formed by ATP implantation 102 under the fins 104a and 104b of FinFET transistors to reduce sub-threshold source-to-drain leakage and Drain-Induced Barrier Lowering (DIBL), It is difficult and challenging to control the location and spread of the ATP layers with respect to the fins 104a and 104b due to natural variation of implant projection range, spread of projection range, and random dopant fluctuation during subsequent activation process of the ATP layers. Specifically, when the ion implantation operation is carried out through the fins 104a and 104b, dopant fluctuation results in mismatches between the fins 104a and 104b. The performance of the FinFET transistors is also closely related to the location of the ATP implantation with respect to the fins. For example, an ATP implantation 102 formed too deep beneath the fins 104a and 104b may result in an undesirable current path below active fin, causing punch-through. Moreover, improperly placing the ATP implantation 102 may damage or destroy the fins 104a and 104b. When the ATP implantation 102 is not formed deep enough into the substrate, the dopant impurities of the ATP layers occupy the lower portions of the fins 104a and 104b, especially after the high heat treatments used in semiconductor manufacturing. These high heat treatments cause back-diffusion from the ATP layers into the fins 104 and 104b. Referring to FIG. 2, ATP implantation 202 may also result in a tail inside the fin regions 204, which may degrade the on-current of FinFET transistors due to too high threshold voltage from the portion of tin having a high doping concentration.

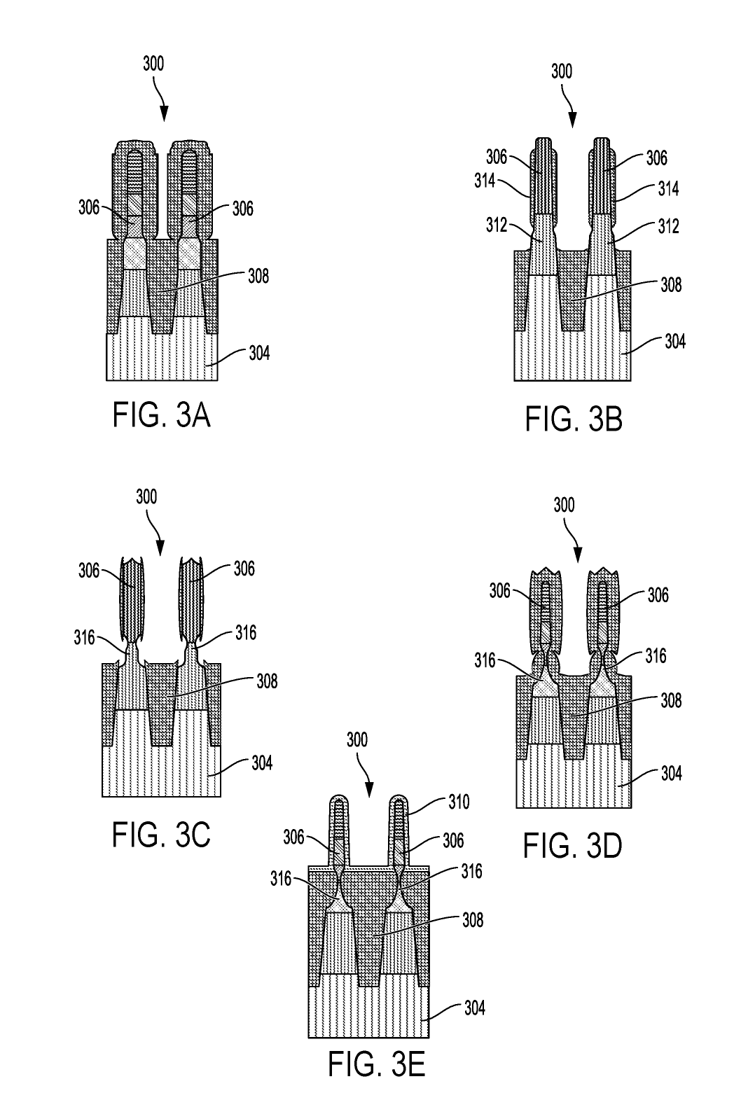

FIGS. 3A-3E show a process of forming a semiconductor structure 300 in accordance with one aspect of the invention. FIG. 3A shows a semiconductor substrate including a bulk semiconductor material 304. A plurality of fins 306 are formed from the bulk semiconductor material 304. Shallow trench isolation (STI) trenches 308 are then formed or etched between the plurality of fins 306.

FIG. 3B shows a plurality of spacers 312 formed on sidewalls 314 of the plurality of fins 306, e.g., by dry or isotropic etching. The sidewalls 314 provide protection to most of fins 306 except for exposed fin bottom portions 316 where isolation is formed as shown in FIG. 3C. In particular, FIG. 3C shows selective etching (e.g., isotropic etching) of exposed fin bottom portions 316 by trimming down, which is then followed by selective oxidation of the remaining Si of the fin bottom portions 316 as shown in FIG. 3D. The spacers 312 in FIG. 3B may include nitrides, which function to protect sidewalk 314 of active tin during selective etching and oxidation of tin bottom portions 316. Fin bottom portions 316 may be selectively oxidized to consume the remaining Si at approximately 500˜900° Celsius for approximately 30˜600 seconds. In one aspect, fin bottom portions 316 are removed by selective oxidation. In another aspect, fin bottom portions 316 are etched by isotropic etching. The process in FIGS. 3A-3D of eliminating the conducting Si and replacing insulating oxide material at fin bottom portions 316 can prevent punch-through current flow.

Next, a hardmask 310 is then formed around fins 306 as shown in FIG. 3E. Hardmask 310 may be formed by fin-trim oxidation at approximately 500˜900° Celsius for approximately 30˜300 seconds. The fin-trim oxidation provides STI trenches 308 with recessed and self-aligned fin-trim silicon oxide. In another aspect, the forming of the hardmask 310 further includes depositing silicon oxide to the top of fin bottoms 316. In another aspect, hardmask 310 is formed by oxidizing a layer of silicon oxide around fins 306.

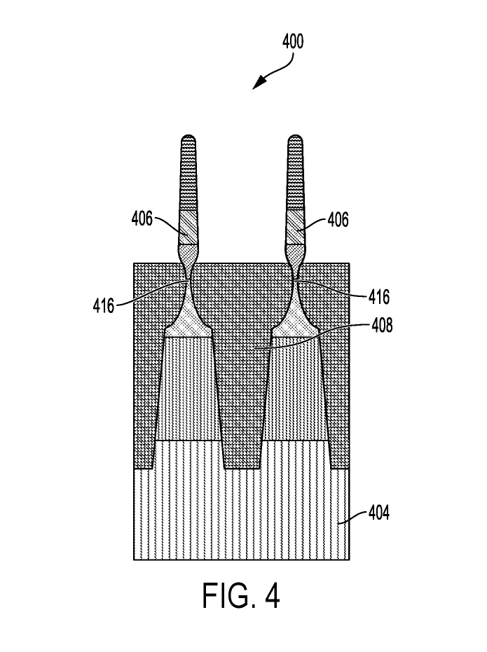

FIG. 4 shows a semiconductor device 400 in accordance to one aspect of the invention. The semiconductor device 400 may comprise a plurality of fins 406 formed on a semiconductor substrate 402 including a bulk semiconductor material 404. The semiconductor device 400 may further comprise plurality of shallow trench isolation (STI) trenches 408 formed between the plurality of fins 406, a hardmask 410 formed around the plurality of fins 406. As explained above, the side walls 414 of the plurality of fins 406 may be formed by selectively oxidation. The plurality of fins 406 may further comprise fin bottom portions 416 formed below the fins 406 through the process explained, e.g., in FIGS. 3A-3E above. Fin bottom portions 416 may further comprise exposed portions which may be etched by selective oxidation or isotropic etching. Hardmask 410 may be formed by depositing silicon oxide to the top of fin bottom portions 416, oxidizing a layer of silicon oxide around fins 406, and then with fin-trim oxidation.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another—even if they do not directly physically touch each other. For instance, a first die may be coupled to a second die in a package even though the first die is never directly physically in contact with the second die.

One or more of the components, steps, features and/or functions illustrated in the figures may be rearranged and/or combined into a single component, step, feature or function or embodied in several components, steps, or functions. Additional elements, components, steps, and/or functions may also be added without departing from novel features disclosed herein. The apparatus, devices, and/or components illustrated in the figures may be configured to perform one or more of the methods, features, or steps described herein. The novel algorithms described herein may also be efficiently implemented in software and/or embedded in hardware.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover: a; b; c; a and b; a and c; b and c; and a, b and c. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112, sixth paragraph, unless the element is expressly recited using the phrase “means for” or, in the case of a method claim, the element is recited using the phrase “step for.”

1-10. (canceled)

11. A semiconductor device, comprising:
a plurality of fins formed on a semiconductor substrate including a bulk semiconductor material;
a plurality of shallow trench isolation (STI) trenches formed between the plurality of fins;
a hardmask formed around the plurality of fins; and
a plurality of fin bottom portions formed below the plurality of fins.

12. The semiconductor device of claim 11, further comprising a plurality of spacers formed on sidewalls of the plurality of fins.

13. The semiconductor device of claim 12, wherein the plurality of fin bottom portions are formed by selective oxidation.

14. The semiconductor device of claim 12, wherein the plurality fin bottom portions are etched by isotropic etching.

15. The semiconductor device of claim 13, wherein the plurality of spacers are formed by dry and/or isotropic etching.

16. The semiconductor device of claim 12, wherein the hardmask is formed by depositing silicon oxide to the top of the plurality of fin bottom portions.

17. The semiconductor device of claim 14, wherein exposed portions of the plurality of fin bottom portions are formed by selective oxidation.

18. The semiconductor device of claim 12, wherein the hardmask is formed by oxidizing a layer of silicon oxide around the plurality of fins.

19. The semiconductor device of claim 12, wherein the hardmask is formed by fin-trim oxidation.
